(19) United States
(12) Patent Application Publication
(10) Pub. No.: US 2018/0114862 A1
(43) Pub. Date: Apr. 26, 2018

(54) METHOD FOR PRODUCING THIN FILM TRANSISTOR, AND THIN FILM TRANSISTOR

(71) Applicant: NISSHA PRINTING CO., LTD., Kyoto-shi, Kyoto (JP)

(72) Inventors: Hideaki NADA, Kyoto-shi, Kyoto (JP); Ryomei OMOTE, Kyoto-shi, Kyoto (JP); Hirotaka SHIGENO, Kyoto-shi, Kyoto (JP); Yoshihiro SAKATA, Kyoto-shi, Kyoto (JP); Shuzo OKUMURA, Kyoto-shi, Kyoto (JP)

(21) Appl. No.: 15/558,673

(22) PCT Filed: Mar. 2, 2016
(86) PCT No.: PCT/JP2016/056477

§ 371 Date: Sep. 15, 2017

(30) Foreign Application Priority Data
Mar. 30, 2015 (JP) 2015-070347

(51) Int. Cl. H01L 29/786; H01L 29/66; H01L 21/02; H01L 21/4763; H01L 21/467; H01L 29/24; H01L 29/49; H01L 21/027; H01L 27/12

(52) U.S. Cl. CPC H01L 29/7869; H01L 27/1262; H01L 21/02565; H01L 21/47635; H01L 21/467; H01L 29/24; H01L 29/4908; H01L 21/0274; H01L 27/1225; H01L 27/1218; H01L 27/1251; H01L 29/78603; H01L 21/02422; H01L 27/127; H01L 29/66969

(57) ABSTRACT

A method for producing a thin film transistor and a thin film transistor that can suppress deterioration and variation in performance are provided. A method for producing a thin film transistor includes: forming an oxide semiconductor layer on a first main surface of a substrate; forming a first conductive layer on the oxide semiconductor layer, while forming a second conductive layer on a second main surface of the substrate; forming mask layers collectively on the first conductive layer and the second conductive layer; and bringing the first conductive layer and the second conductive layer collectively into contact with etching liquid so that partial regions of the first conductive layer and the second conductive layer are removed, so as to form a source electrode and a drain electrode on the oxide semiconductor layer, while forming a gate electrode on the second main surface of the substrate.

### TECHNICAL FIELD

The present invention relates to a thin film transistor using oxide semiconductor as a semiconductor layer.

### BACKGROUND ART

In recent years, along with increasing needs for a thinner, more flexible and lighter transistor, a high polymer film such as polyethylene naphthalate (PEN) or polyimide (PI) is used as a substrate material. As a result, oxide semiconductor is used as a semiconductor layer, which can be formed as a film under a heat-resistant temperature thereof. In addition, a photolithography method or a printing method is used for forming a source electrode, a drain electrode, and a gate electrode constituting the thin film transistor.

Patent Citation 1 describes a thin film transistor using a gate insulating film as a substrate (base), in which electrodes and semiconductor layers are formed by the printing method.

### PRIOR ART CITATIONS

### Patent Citation

Patent Citation 1: JP-A-2006-186294

### SUMMARY OF INVENTION

### Technical Problem

In a production process of a transistor, thermal processing such as film formation or thermal treatment is repeatedly performed. For example, it is performed in vacuum film formation such as sputtering or vapor deposition, or in drying after applying process. Due to this thermal processing, the substrate may be expanded or contracted resulting in a change in dimensions of the substrate. In a production process of a transistor by the photolithography method, film formation of a layer and exposure process or the like for forming a mask layer are performed for each layer, and hence thermal treatment is performed each time when forming each layer resulting in a change in dimensions of the substrate in each step. Therefore, it is difficult to control positions for forming the source electrode and the drain electrode with respect to the gate electrode. As a result, the transistor cannot be produced as designed, and a variation occurs in performance of the transistor resulting in deterioration of production yield.

Therefore, it is an object of the present invention to provide a method for producing a thin film transistor, which can suppress deterioration and variation in performance, and a thin film transistor.

### Technical Solution

According to one aspect of the present invention, a method for producing a thin film transistor, which can achieve the above-described object, includes:

forming an oxide semiconductor layer on a first main surface of a substrate;

forming a first conductive layer on the oxide semiconductor layer, while forming a second conductive layer on a second main surface of the substrate;

forming mask layers collectively on the first conductive layer and the second conductive layer; and

bringing the first conductive layer and the second conductive layer collectively into contact with etching liquid so that partial regions of the first conductive layer and the second conductive layer are removed, so as to form a source electrode and a drain electrode on the oxide semiconductor layer, while forming a gate electrode on a second main surface of the substrate. Because the method for producing a thin film transistor according to the present invention includes the step of forming mask layers collectively on the first conductive layer and the second conductive layer, even if the substrate is thermally expanded or contracted, a positional relationship among the source electrode, the drain electrode, and the gate electrode can be easily maintained. As a result, performance deterioration of the transistor due to misregistration of the gate electrode with respect to the source electrode and the drain electrode can be suppressed. In addition, in the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film. In addition, according to a method for producing the thin film transistor of the present invention, since the source electrode, the drain electrode, and the gate electrode are formed by photolithography, the channel length can be controlled so as to be 10 μm or less, and it is possible to realize the microfabrication of the circuit.

According to a method for producing a thin film transistor of the present invention, it is preferable that the method further includes:

forming a mask layer to cover between the source electrode and the drain electrode after forming the source electrode and the drain electrode; and

bringing the oxide semiconductor layer into contact with etching liquid so as to remove regions of the oxide semiconductor layer, which are not covered with the source electrode, the drain electrode, or the mask layer. Since the oxide semiconductor layer is etched as described above, etching width can be aligned between the source electrode and the oxide semiconductor layer, and etching width can be aligned between the drain electrode and the oxide semiconductor layer. In this way, separately from the source electrode and the drain electrode, the terminal electrodes and via electrodes can be formed on the substrate.

According to a method for producing a thin film transistor of the present invention, it is preferable that the oxide semiconductor layer contains In, Ga, Zn, and O. Electron mobility of IGZO is as high as 10 cm²/V·sec among the oxide semiconductors, and hence operating speed of the transistor can be improved.

According to a method for producing a thin film transistor of the present invention, it is preferable that the first conductive layer and the second conductive layer are made of Cu. It is because Cu has a high electric conductivity, as well as is inexpensive and superior in heat resistance.

According to a method for producing a thin film transistor of the present invention, it is preferable that the mask layer is made of a dry film resist. Compared with the case where the mask layer is formed of a liquid resist, it is not necessary to dry the solvent after applying the resist, and hence productivity can be enhanced if the mask layer is made of a dry film resist.

According to another aspect of the present invention, a thin film transistor, which can achieve the above-described object, comprises:

a substrate;

an oxide semiconductor layer formed on a first main surface of the substrate;

a source electrode formed on the oxide semiconductor layer;

a drain electrode formed on the oxide semiconductor layer; and

a gate electrode formed on a second main surface of the substrate.

In the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film.

According to a thin film transistor of the present invention, it is preferable that the oxide semiconductor layer contains In, Ga, Zn, and O.

It is preferable that the source electrode, the drain electrode, and the gate electrode are formed by collective photolithography and collective wet etching. According to the method for producing the thin film transistor of the present invention, since the source electrode, the drain electrode, and the gate electrode are formed by photolithography, the channel length can be controlled so as to be 10 μm or less and it is possible to realize the microfabrication of the circuit. In addition, because the source electrode, the drain electrode, and the gate electrode are formed by collective photolithography and collective wet etching, even if the substrate is thermally expanded or contracted, a positional relationship among the source electrode, the drain electrode, and the gate electrode can be easily maintained. As a result, performance deterioration of the transistor due to misregistration of the gate electrode with respect to the source electrode and the drain electrode can be suppressed.

According to another aspect of the present invention, a thin film transistor r, which can achieve the above-described object, comprises:

a substrate;

a first oxide semiconductor layer formed on a first main surface of the substrate;

a second oxide semiconductor layer formed on a second main surface of the substrate;

a first transistor including
a first gate electrode formed on the first oxide semiconductor layer, and
a first source electrode and a first drain electrode formed on the second oxide semiconductor layer; and

a second transistor including
a second gate electrode formed on the second oxide semiconductor layer, and
a second source electrode and a second drain electrode formed on the first oxide semiconductor layer.

In the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film. In the thin film transistor of the present invention, two transistors are arranged in different directions so as to sandwich the substrate, and hence an arrangement interval between neighboring transistors can be decreased so that the integration degree of the circuit can be enhanced.

It is preferable that the first source electrode or the first drain electrode and the second source electrode or the second drain electrode are arranged to overlap each other. Since an arrangement interval between neighboring transistors can be decreased so that the integration degree of the circuit can be enhanced.

It is preferable that a conductive type of the first oxide semiconductor layer and a conductive type of the second oxide semiconductor layer have opposite polarities, and the first transistor and the second transistor are structured in a complementary manner. In this way, the first transistor and the second transistor can be arranged to form a CMOS structure of a metal oxide semiconductor (MOS).

It is preferable that the first drain electrode and the second drain electrode are arranged to overlap each other, a through hole is formed in the substrate in a region in which the first drain electrode and the second drain electrode overlap each other, and the first drain electrode and the second drain electrode are connected to each other via the through hole. Because the first drain electrode and the second drain electrode are arranged to overlap each other, an arrangement interval between the transistors adjacent to each other can be reduced. In addition, because the first drain electrode and the second drain electrode are connected to each other via the through hole, the length of a wiring for connecting the first drain electrode and the second drain electrode can be shortened, and it is not necessary to secure an additional space for the wiring.

It is preferable that the first oxide semiconductor layer or the second oxide semiconductor layer contains In, Ga, Zn, and O.

It is preferable that the substrate is made of a high polymer film, and thickness of the substrate is 0.1 μm or more to 50 μm or less. If the substrated is made of a high polymer film having a thickness of 0.1 μm or more to 50 μm or less, it is possible to maintain the number of carriers that move in the channel region per unit time, and the substrate can be easily handled.

### Advantageous Effects

In the method for producing a thin film transistor according to the present invention, even if the substrate is thermally expanded or contracted, a positional relationship among the source electrode, the drain electrode, and the gate electrode can be easily maintained. As a result, performance deterioration of the transistor due to misregistration of the gate electrode with respect to the source electrode and the drain electrode can be suppressed. In addition, according to the method for producing the thin film transistor of the present invention, the channel length can be controlled so as to be 10 μm or less, and it is possible to realize the microfabrication of the circuit.

In the method of producing the transistor and the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film.

In the thin film transistor including the first transistor and the second transistor of the present invention, two transistors are arranged in different directions so as to sandwich the substrate, and hence an arrangement interval between neighboring transistors can be decreased so that the integration degree of the circuit can be enhanced.

### BRIEF DESCRIPTION OF DRAWINGS

FIG. 1 is a cross-sectional view illustrating a step of a method for producing a thin film transistor according to an embodiment of the present invention.

FIG. 2 is a cross-sectional view illustrating a step of the method for producing a thin film transistor according to an embodiment of the present invention.

FIG. 3 is a cross-sectional view illustrating a step of the method for producing a thin film transistor according to an embodiment of the present invention.

FIG. 4 is a cross-sectional view illustrating a step of the method for producing a thin film transistor according to an embodiment of the present invention.

FIG. 5 is a cross-sectional view illustrating a step of the method for producing a thin film transistor according to an embodiment of the present invention.

FIG. 6 is a cross-sectional view illustrating a step of the method for producing a thin film transistor according to an embodiment of the present invention.

FIG. 7 is a cross-sectional view illustrating a step of the method for producing a thin film transistor according to an embodiment of the present invention.

FIG. 8 is a cross-sectional view illustrating a step of the method for producing a thin film transistor according to an embodiment of the present invention.

FIG. 9 is a cross-sectional view illustrating a step of the method for producing a thin film transistor according to an embodiment of the present invention.

FIG. 10 is a cross-sectional view illustrating another example of the thin film transistor according to an embodiment of the present invention.

FIG. 11 is a cross-sectional view illustrating another example of the thin film transistor according to an embodiment of the present invention.

FIG. 12 is a schematic diagram illustrating a structure of a CMOS circuit.

FIG. 13 is a cross-sectional view illustrating another example of the thin film transistor according to an embodiment of the present invention.

FIG. 14 is a cross-sectional view illustrating a step of the method for producing a thin film transistor according to a reference example.

FIG. 15 is a cross-sectional view illustrating a step of the method for producing a thin film transistor according to the reference example.

FIG. 16 is a cross-sectional view illustrating a step of the method for producing a thin film transistor according to the reference example.

FIG. 17 is a cross-sectional view illustrating a step of the method for producing a thin film transistor according to the reference example.

FIG. 18 is a cross-sectional view illustrating a step of the method for producing a thin film transistor according to the reference example.

FIG. 19 is a cross-sectional view illustrating a step of the method for producing a thin film transistor according to the reference example.

FIG. 20 is a cross-sectional view illustrating a step of the method for producing a thin film transistor according to the reference example.

FIG. 21 is a cross-sectional view illustrating a step of the method for producing a thin film transistor according to the reference example.

### DESCRIPTION OF EMBODIMENTS

Hereinafter, the present invention is described in more detail based on an embodiment. The present invention is not limited to the embodiment described below but can be implemented with modifications within the spirit thereof described above and below, which are included in the technical scope of the present invention. In addition, dimensional ratios of various members illustrated in the drawings may be different from actual dimensional ratios, because priority is put on understanding of features of the present invention.

A method for producing a thin film transistor according to the present invention includes the steps of: (1) forming an oxide semiconductor layer on a first main surface of a substrate; (2) forming a first conductive layer on the oxide semiconductor layer, while forming a second conductive layer on the a second main surface of the substrate; (3) forming mask layers collectively on the first conductive layer and the second conductive layer; and (4) bringing the first conductive layer and the second conductive layer collectively into contact with etching liquid so that partial regions of the first conductive layer and the second conductive layer are removed, so as to form a source electrode and a drain electrode on the oxide semiconductor layer, while to form a gate electrode on the second main surface of the substrate. Because the method for producing a thin film transistor according to the present invention includes the step of (3) forming mask layers collectively on the first conductive layer and the second conductive layer, even if the substrate is thermally expanded or contracted, a positional relationship among the source electrode, the drain electrode, and the gate electrode can be easily maintained. As a result, performance deterioration of the transistor due to misregistration of the gate electrode with respect to the source electrode and the drain electrode can be suppressed.

In addition, a thin film transistor according to the present invention includes a substrate, an oxide semiconductor layer formed on the first main surface of the substrate, a source electrode formed on the oxide semiconductor layer, a drain electrode formed on the oxide semiconductor layer, and a gate electrode formed on the second main surface of the substrate. In the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film.

Further, a thin film transistor of the present invention includes a substrate; a first oxide semiconductor layer formed on the first main surface of the substrate; a second oxide semiconductor layer formed on the second main surface of the substrate; a first transistor including a first gate electrode formed on the first oxide semiconductor layer, and a first source electrode and a first drain electrode formed on the second oxide semiconductor layer; and a second transistor including a second gate electrode formed on the second oxide semiconductor layer, and a second source electrode and a second drain electrode formed on the first oxide semiconductor layer. In the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film. In the thin film transistor of the present invention, two transistors are arranged in different directions so as to sandwich the substrate, and hence an arrangement interval between neighboring transistors can be decreased so that the integration degree of the circuit can be enhanced.

In the present invention, the thin film transistor has thickness direction and surface direction. The thickness direction of the thin film transistor is a direction in which the oxide semiconductor layer and the conductive layer are laminated on the substrate and corresponds to an up and down direction in the drawings. The surface direction of the thin film transistor is perpendicular to the thickness direction and includes a longitudinal direction and a lateral direction. Note that a left and right direction in the drawings corresponds to the lateral direction of the surface direction of the thin film transistor.

The substrate works also as the gate insulating film. The substrate is preferably made of a high polymer film such as polyethylene naphthalate (PEN), polyethylene terephthalate (PET), or polyimide (PI). If the thickness of the substrate is too large, the number of carriers that move between the source electrode and the drain electrode per unit time is decreased. On the other hand, if the thickness of the substrate is too small, the substrate may be bent or broken in a production process of the transistor, and hence the substrate cannot be easily handled. From above discussion, the thickness of the substrate is preferably 0.1 μm or more to 50 μm or less, more preferably 0.5 μm or more to 40 μm or less, and still more preferably 1 μm or more to 30 μm or less.

The oxide semiconductor layer functions as a channel region of the transistor. As a material of the oxide semiconductor layer, for example, it is possible to use ZnO-based material, NiO-based material, TiO-based material, InO-based material, SnO-based material, InGaO-based material, InZnO-based material, InGaZnO-based (IGZO) material, or the like. Among them, it is preferred that the oxide semiconductor layer should contain In, Ga, Zn, and O (hereinafter referred to as “IGZO”). Electron mobility of IGZO is as high as 10 cm²/V·sec, and hence operating speed of the transistor can be improved.

The first conductive layer and the second conductive layer are used for forming electrodes such as a gate electrode, a source electrode, a drain electrode, a terminal electrode, a via electrode, and the like constituting the transistor. As described later in detail with an example of the production method, partial regions of the first conductive layer and the second conductive layer are covered with a mask layer, and the first conductive layer and the second conductive layer are brought into contact with etching liquid, and hence the electrodes can be formed.

For the first conductive layer and the second conductive layer, it is possible to use conductive material such as Al, Ag, C, Ni, Au, Cu, or the like, for example. Among them, it is preferred that the first conductive layer and the second conductive layer should be made of Cu. It is because Cu has a high electric conductivity, as well as is inexpensive and superior in heat resistance.

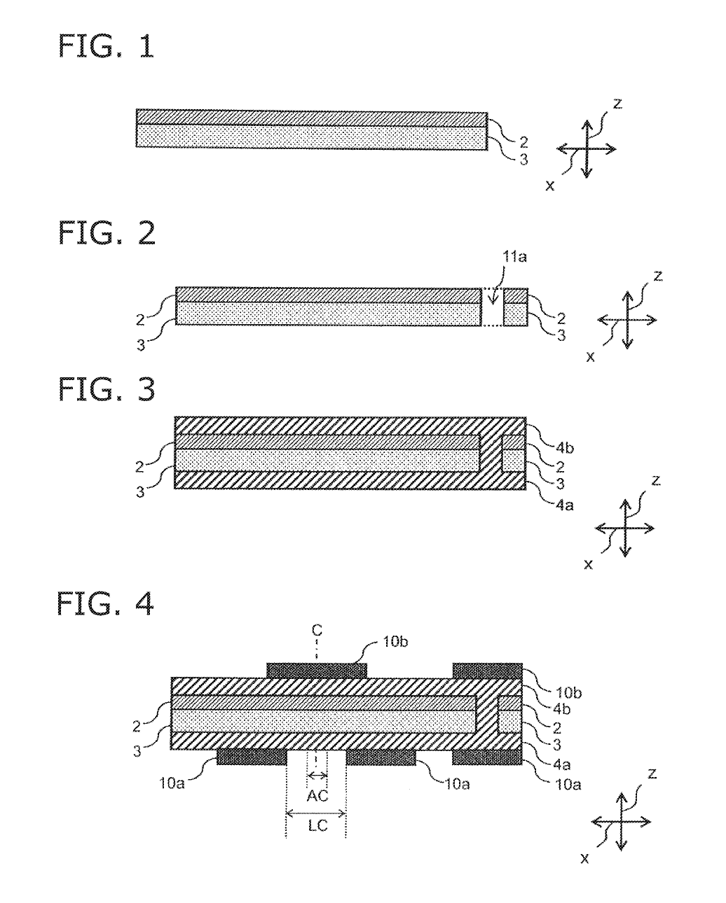

Hereinafter, a preferred example of the method for producing a thin film transistor according to this embodiment is described in detail with reference to the drawings. FIGS. 1 to 9 are cross-sectional views illustrating partial steps of the method for producing a thin film transistor according to an embodiment of this embodiment.

(1) Step of forming the oxide semiconductor layer on the first main surface of the substrate

A polyimide film having a thickness of 25 μm is prepared as a substrate 2. As illustrated in FIG. 1, an oxide semiconductor layer 3 (for example IGZO) is formed on the first main surface of the substrate 2. In FIG. 1, the oxide semiconductor layer 3 is formed on the lower side surface in a thickness direction z of the substrate 2. A method of forming the oxide semiconductor layer 3 is not particularly limited. For example, it is possible to use a vacuum vapor deposition method, a sputtering method, a method of sticking foil-like conductive material, or the like.

Next, in order to form the terminal electrodes and the via electrodes, through holes 11a are formed to penetrate the substrate 2 and the oxide semiconductor layer 3 in the thickness direction z as illustrated in FIG. 2. The through holes 11a are formed by means of punching, laser processing, or the like.

(2) Step of forming the first conductive layer on the oxide semiconductor layer and forming the second conductive layer on the second main surface of substrate

A first conductive layer 4a is formed on the oxide semiconductor layer 3, and a second conductive layer 4b is formed on the second main surface of the substrate 2. In other words, as illustrated in FIG. 3, the first conductive layer 4a is formed on the lower side of the oxide semiconductor layer 3 in the thickness direction z, and the second conductive layer 4b is formed on the upper side of the substrate 2. The first conductive layer 4a and the second conductive layer 4b are formed by means of the vacuum vapor deposition method or the sputtering method, for example, in the same manner as film formation of the oxide semiconductor layer 3 described above.

(3) Step of forming the mask layers collectively on the first conductive layer and the second conductive layer

As illustrated in FIG. 4, for determining positions of the gate electrode, the source electrode, and the drain electrode, mask layers 10a and 10b are formed collectively on the first conductive layer 4a and the second conductive layer 4b, respectively.

Specifically, mask layers 10 (10a and 10b) are formed as follows. Photosensitive resin such as dry film resist or liquid resist is applied onto the first conductive layer 4a and the second conductive layer 4b. As the photosensitive resin, there are a negative type that makes the exposed part become insoluble in the developer and a positive type that makes the exposed part become soluble in the developer. In the following description, a negative type photosensitive resin is exemplified. A first resist is applied onto the first conductive layer 4a, and a second resist is applied onto the second conductive layer 4b. The first resist and the second resist are irradiated with an electron beam or light (ultraviolet rays) so that predetermined circuit patterns are drawn on the first resist and the second resist. At least shapes of the source electrode and the drain electrode are drawn on the first resist, and at least a shape of the gate electrode is drawn on the second resist.

In order to prevent performance deterioration of the transistor, it is preferred, as illustrated in FIG. 4, that a center line C in a left and right direction x of the mask layer 10b for forming the gate electrode should be positioned in a center region AC, when the region (channel length LC) between the source electrode and the drain electrode formed by the mask layer 10a is equally divided into three parts in the left and right direction x.

The channel length LC is preferably 20 μm or less, more preferably 15 μm or less, and still more preferably 10 μm or less. As the channel length LC is shorter, operating speed of the transistor can be higher.

Using an exposure apparatus (not shown) that can collectively expose both sides of the substrate 2, both the first resist and the second resist are collectively exposed so that the circuit patterns can be transferred and burned onto the first resist and the second resist.

When the first resist and the second resist are brought into contact with the developer, unexposed parts of the resists are dissolved in the developer. As a result, exposed parts of the first resist and the second resist are left as the mask layers 10a and 10b on the first conductive layer 4a and the second conductive layer 4b.

The mask layer 10 can be formed of a dry film resist or a liquid resist, but it is preferably formed of the dry film resist. Compared with the case where the mask layer 10 is formed of a liquid resist, it is not necessary to dry the solvent after applying the resist, and hence productivity can be enhanced.

(4) Step of bringing the first conductive layer and the second conductive layer collectively into contact with the etching liquid so that partial regions of the first conductive layer and the second conductive layer are removed, so as to form the source electrode and the drain electrode on the oxide semiconductor layer, while to form the gate electrode on the second main surface of substrate.

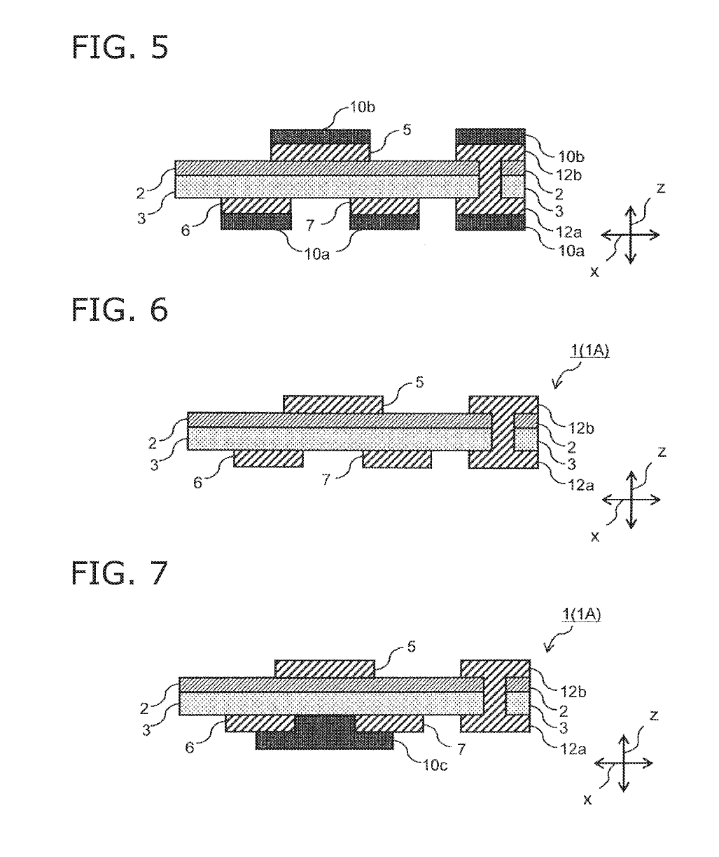

Next, the first conductive layer 4a, on which the mask layer 10a is formed, and the second conductive layer 4b, on which the mask layer 10b is formed, are collectively brought into contact with etching liquid. With this operation, partial regions of the first conductive layer 4a and the second conductive layer 4b are removed as illustrated in FIG. 5.

As illustrated in FIG. 6, the mask layers 10a and 10b are brought into contact with stripping liquid to dissolve, and hence the mask layers 10a and 10b are removed. A thin film transistor can be obtained, in which a source electrode 6 and a drain electrode 7 are formed on the oxide semiconductor layer 3, and a gate electrode 5 is formed on the second main surface of the substrate 2.

In other words, as illustrated in FIG. 6, a thin film transistor 1 (1A) of the present invention has the source electrode 6, the drain electrode 7, and the gate electrode 5, which are formed by collective photolithography and collective wet etching. Therefore, even if the substrate 2 is thermally expanded or contracted, a positional relationship among the source electrode 6, the drain electrode 7, and the gate electrode 5 can be easily maintained. As a result, it is possible to suppress performance deterioration of the transistor due to misregistration of the gate electrode 5 with respect to the source electrode 6 and the drain electrode 7.

(5) Step of forming the mask layer to cover between the source electrode and the drain electrode after forming the source electrode and the drain electrode

As illustrated in FIG. 7, in order to prevent a partial region of the oxide semiconductor layer 3 that functions as the channel region from being etched, a mask layer 10c is formed to cover the lower side surface of the thickness direction z of the substrate 2. The mask layer 10c is formed, for example, by printing the resist only in the channel region. In addition to the formed mask layer 10c, the source electrode 6, the drain electrode 7, and a terminal electrode 12a function as a mask.

(6) Step of bringing the oxide semiconductor layer into contact with the etching liquid so as to remove regions of the oxide semiconductor layer, which are neither covered with the source electrode, the drain electrode, nor the mask layer

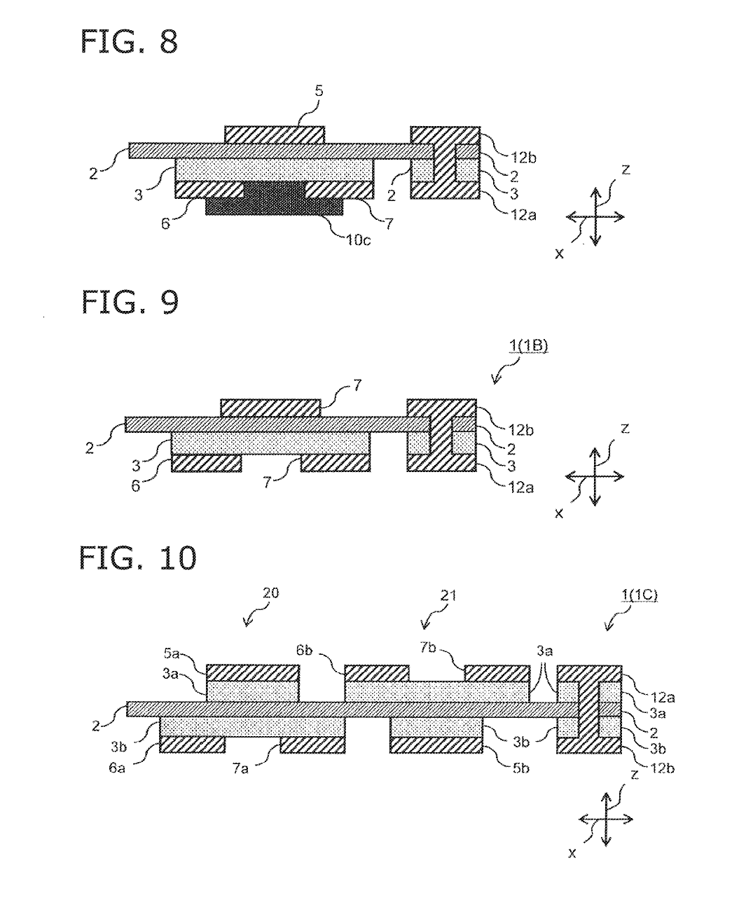

As illustrated in FIG. 8, the oxide semiconductor layer 3 is brought into contact with the etching liquid so as to remove regions of the oxide semiconductor layer 3, which are neither covered with mask layer 10c, the source electrode 6, nor the drain electrode 7. In this way, in the left and right direction x, etching width can be aligned between the left side end of the source electrode 6 and the left side end of the oxide semiconductor layer 3. In addition, in the left and right direction x, etching width can be aligned between the right side end of the drain electrode 7 and the right side end of the oxide semiconductor layer 3. In this way, separately from the source electrode 6 and the drain electrode 7, the terminal electrodes 12a and 12b and via electrodes (not shown) can be formed on the substrate 2.

As illustrated in FIG. 9, the mask layer 10c is brought into contact with the stripping liquid to dissolve, and hence the mask layer 10c is removed. In this way, the thin film transistor 1 (1B) is produced.

Next, a thin film transistor of another implementation, which is different from the thin film transistor illustrated in FIG. 9, is described with reference to FIGS. 10 to 13. Note that, in the description with reference to FIGS. 10 to 13, overlapping description of the same part as described above is omitted. FIGS. 10, 11, and 13 illustrate cross-sectional views in the thickness direction z of the thin film transistor.

A thin film transistor 1(1C) of the present invention illustrated in FIG. 10 includes a substrate 2; a first oxide semiconductor layer 3a formed on a first main surface of the substrate 2; a second oxide semiconductor layer 3b formed on a second main surface of the substrate 2; a first transistor 20 including a first gate electrode 5a formed on the first oxide semiconductor layer 3a, and a first source electrode 6a and a first drain electrode 7a formed on the second oxide semiconductor layer 3b; and a second transistor 21 including a second gate electrode 5b formed on the second oxide semiconductor layer 3b, and a second source electrode 6b and a second drain electrode 7b formed on the first oxide semiconductor layer 3a.

The first gate electrode 5a of the first transistor 20 is formed between the first source electrode 6a and the first drain electrode 7a, while the second gate electrode 5b of the second transistor 21 is formed between the second source electrode 6b and the second drain electrode 7b.

What contributes to operation of the first transistor 20 is the second oxide semiconductor layer 3b on which the first source electrode 6a and the first drain electrode 7a are formed. On the other hand, what contributes to operation of the second transistor 21 is the first oxide semiconductor layer 3a on which the second source electrode 6b and the second drain electrode 7b are formed.

In this way, in the thin film transistor 1C of the present invention, two transistors are arranged in different directions so as to sandwich the substrate 2, and hence an arrangement interval between neighboring transistors can be decreased so that the integration degree of the circuit can be enhanced.

As to the thin film transistor 1C, it is preferred that the first gate electrode 5a, the first source electrode 6a, the first drain electrode 7a, the second gate electrode 5b, the second source electrode 6b, and the second drain electrode 7b should be formed by collective photolithography and collective wet etching. Even if the substrate 2 is thermally expanded or contracted, a positional relationship among the first gate electrode 5a, the first source electrode 6a, and the first drain electrode 7a, and a positional relationship among the second gate electrode 5b, the second source electrode 6b, and the second drain electrode 7b can be easily maintained. As a result, it is possible to suppress performance deterioration of the transistors, due to misregistration of the first gate electrode 5a with respect to the first source electrode 6a and the first drain electrode 7a, and misregistration of the second gate electrode 5b with respect to the second source electrode 6b and the second drain electrode 7b.

According to the present invention, by changing the circuit pattern drawn on the mask layer 10 by the photolithography method, a plurality of transistors can be produced in the same manner as the case where one transistor is produced, and hence productivity can be enhanced.

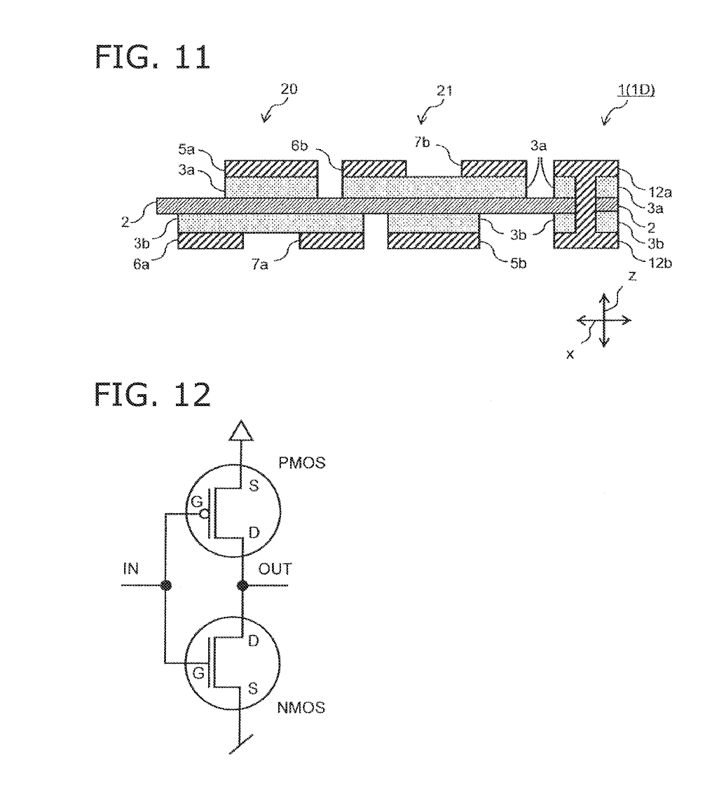

In order to further increase the integration degree of the circuit, it is preferred that the first source electrode 6a or the first drain electrode 7a and the second source electrode 6b or the second drain electrode 7b should be arranged to overlap each other. With this structure of the two transistors, an arrangement interval between neighboring transistors can be further decreased. In the thin film transistor 1(1D) illustrated in FIG. 11, the first drain electrode 7a and the second source electrode 6b are arranged to overlap each other, but in accordance with a conductive type of the semiconductor or a circuit type, the first source electrode 6a and the second source electrode 6b may be arranged to overlap each other, or the first source electrode 6a and the second drain electrode 7b may be arranged to overlap each other, or the first drain electrode 7a and the second drain electrode 7b may be arranged to overlap each other.

It is preferred that the conductive type of the first oxide semiconductor layer 3a and the conductive type of the second oxide semiconductor layer 3b should have opposite polarities, and that the first transistor 20 and the second transistor 21 should be complementary. In this way, the first transistor 20 and the second transistor 21 can be arranged to form a CMOS structure of a metal oxide semiconductor (MOS).

FIG. 12 is a schematic diagram illustrating a structure of a CMOS circuit. A CMOS is a circuit structure in which a pair of PMOS and NMOS is used, and operation characteristics of the PMOS and the NMOS are combined in a complementary manner, and has a feature that it can operate at low voltage so that power consumption can be reduced. In FIG. 9, G denotes the gate, S denotes the source, D denotes the drain, IN denotes the input, and OUT denotes the output.

It is sufficient if a conductive type of the first oxide semiconductor layer 3a and a conductive type of the second oxide semiconductor layer 3b have opposite polarities. The first oxide semiconductor layer 3a may be p-type while the second oxide semiconductor layer 3b may be n-type, or the first oxide semiconductor layer 3a may be n-type while the second oxide semiconductor layer 3b may be p-type.

For the first oxide semiconductor layer 3a and the second oxide semiconductor layer 3b, it is possible to use ZnO-based material, NiO-based material, TiO-based material, InO-based material, SnO-based material, InGaO-based material, InZnO-based material, InGaZnO-based (IGZO) material, or the like, for example, similarly to the oxide semiconductor layer 3 described above. Among them, it is preferred that the first oxide semiconductor layer 3a or the second oxide semiconductor layer 3b should contain In, Ga, Zn, and O (IGZO). Electron mobility of IGZO is as high as 10 cm²/V·sec, and hence operating speed of the transistor can be improved.

For example, IGZO working as an n-type transistor can be used for the first oxide semiconductor layer 3a, while SnO working as a p-type transistor can be used for the second oxide semiconductor layer 3b.

If a conductive type of the first oxide semiconductor layer 3a and a conductive type of the second oxide semiconductor layer 3b have opposite polarities and if the first transistor 20 and the second transistor 21 are structured in a complementary manner, the thin film transistor can be configured as follows. Specifically, as illustrated in FIG. 13, the thin film transistor 1(1E) preferably has the structure, in which the first drain electrode 7a and the second drain electrode 7b are arranged to overlap each other, a through hole 11b is formed in the thickness direction of the substrate 2 in a region in which the first drain electrode 7a and the second drain electrode 7b overlap each other, and the first drain electrode 7a is connected to the second drain electrode 7b via the through hole 11b. Note that the through hole 11b is formed separately from the through hole 11a for connecting the terminal electrode 12a and the terminal electrode 12b. Because the first drain electrode 7a and the second drain electrode 7b are arranged to overlap each other, an arrangement interval between the first transistor 20 and the second transistor 21 in the left and right direction x in FIG. 13 can be reduced. In addition, because the first drain electrode 5a and the second drain electrode 5b are connected to each other via the through hole 11b, the length of a wiring for connecting the first drain electrode 5a and the second drain electrode can be shortened, and it is not necessary to secure an additional space for the wiring. Note that, similarly to the through hole 11a for forming the terminal electrodes or via electrodes, the through hole 11b can be formed by means of punching, laser processing, or the like.

### Reference Example

As a reference, a method for producing a thin film transistor in a case where the individual layers are formed on a first main surface of the substrate is described with reference to FIGS. 14 to 21. FIGS. 14 to 21 are a cross-sectional views illustrating steps of the method for producing a thin film transistor according to the reference example. In FIG. 14, the first conductive layer 4a is formed on the first main surface of the substrate 2. The first conductive layer 4a is formed by the vacuum vapor deposition method or the sputtering method.

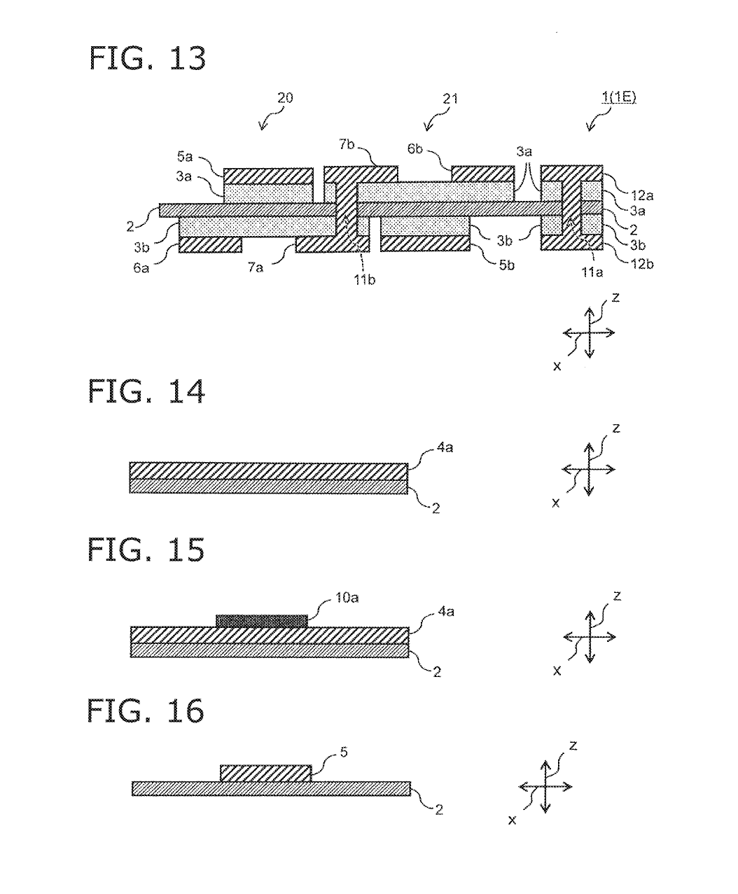

As illustrated in FIG. 15, the mask layer 10a for forming a gate electrode is formed on the first conductive layer 4a. The mask layer 10a is formed, for example, by applying and drying photoresist on the first conductive layer 4a, then transferring a circuit pattern onto the photoresist using the exposure apparatus, and finally dissolving unnecessary resist by the developer so as to remove the same.

In the state where the mask layer 10a is formed on the first conductive layer 4a, the first conductive layer 4a is etched by the etching liquid. Next, the mask layer 10a is brought into contact with the stripping liquid so as to peel and remove the mask layer 10a. In this way, as illustrated in FIG. 16, the gate electrode 5 is formed on the first main surface of the substrate 2.

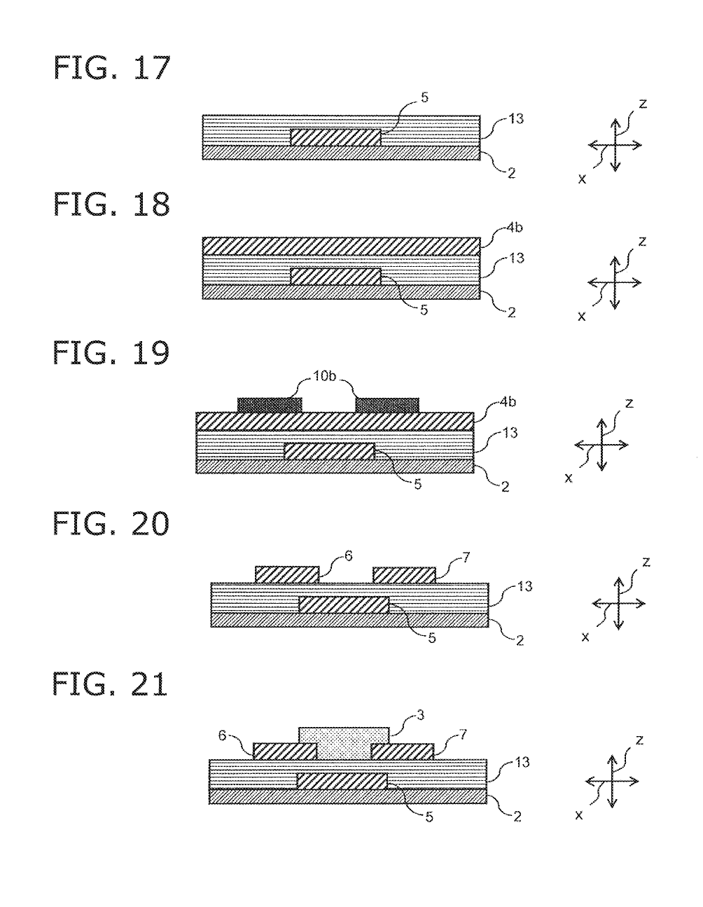

As illustrated in FIG. 17, a gate insulating film 13 is formed on the first main surface of the substrate 2 and the gate electrode 5. For forming the gate insulating film 13, it is possible to use a spin coating method, the vacuum vapor deposition method, or the sputtering method, for example. In addition, when the thin film transistor is formed by a roll to roll method, it is possible to use an applying method such as a screen printing method, a gravure coater method, a die coating method, or a spraying method.

As illustrated in FIG. 18, the second conductive layer 4b is formed on the gate insulating film 13. For forming the second conductive layer 4b, it is possible to use the vacuum vapor deposition method or the sputtering method similarly to the forming of the first conductive layer 4a.

As illustrated in FIG. 19, the mask layer 10b for forming the source electrode and the drain electrode is formed on the second conductive layer 4b. The mask layer 10b is formed, similarly to the mask layer 10a, by applying and drying photoresist on the second conductive layer 4b, then transferring a circuit pattern onto the photoresist using the exposure apparatus, and finally dissolving unnecessary resist by the developer so as to remove the same.

In the state where the mask layer 10b is formed on the second conductive layer 4b, the second conductive layer 4b is etched by the etching liquid. Next, the mask layer 10b is brought into contact with the stripping liquid so as to peel and remove the mask layer 10b. In this way, as illustrated in FIG. 20, the source electrode 6 and the drain electrode 7 are formed on the gate insulating film 13.

Finally, as illustrated in FIG. 21, the oxide semiconductor layer 3 is formed on the same surface as the source electrode 6 and the drain electrode 7 on the gate insulating film 13. For forming the oxide semiconductor layer 3, it is possible to use the vacuum vapor deposition method.

Compared with the embodiment of the present invention, as to the laminating order and the production method of the thin film transistor according to the reference example, the exposure process and the like are performed respectively for forming the mask layer 10a for forming the gate electrode 5 and for forming the mask layer 10b for forming the source electrode 6 and the drain electrode 7. Therefore, when exposing with reference to alignment marks, deviations in registration accuracy of the apparatus are apt to be accumulated. In addition, when the substrate is thermally expanded or contracted, it is difficult to control the forming positions of the source electrode and the drain electrode with respect to the gate electrode.

### REFERENCE SIGNS LIST

1, 1A, 1B, 1C, 1D, 1E thin film transistor
2 substrate
3 oxide semiconductor layer
3a first oxide semiconductor layer
3b second oxide semiconductor layer
4a first conductive layer
4b second conductive layer
5 gate electrode
5a first gate electrode
5b second gate electrode
6 source electrode
6a first source electrode
6b second source electrode
7 drain electrode
7a first drain electrode
7b second drain electrode
8 source/drain electrode
10, 10a, 10b, 10c mask layer
11a, 11b through hole
12a, 12b terminal electrode
20 first transistor
21 second transistor

1. A method for producing a thin film transistor, the method comprising:
forming an oxide semiconductor layer on a first main surface of a substrate;
forming a first conductive layer on the oxide semiconductor layer, while forming a second conductive layer on a second main surface of the substrate;
forming mask layers collectively on the first conductive layer and the second conductive layer; and
bringing the first conductive layer and the second conductive layer collectively into contact with etching liquid so that partial regions of the first conductive layer and the second conductive layer are removed, so as to form a source electrode and a drain electrode on the oxide semiconductor layer, while forming a gate electrode on the second main surface of the substrate.

2. The method for producing a thin film transistor according to claim 1, further comprising:
forming a mask layer to cover between the source electrode and the drain electrode after forming the source electrode and the drain electrode; and
bringing the oxide semiconductor layer into contact with etching liquid so as to remove regions of the oxide semiconductor layer, which are not covered with the source electrode, the drain electrode, or the mask layer.

3. The method for producing a thin film transistor according to claim 1, wherein the oxide semiconductor layer contains In, Ga, Zn, and O.

4. The method for producing a thin film transistor according to claim 1, wherein the first conductive layer and the second conductive layer are made of Cu.

5. The method for producing a thin film transistor according to claim 1, wherein the mask layer is made of a dry film resist.

6. A thin film transistor comprising:
a substrate;
an oxide semiconductor layer formed on first main surface of the substrate;
a source electrode formed on the oxide semiconductor layer;
a drain electrode formed on the oxide semiconductor layer; and
a gate electrode formed on a second main surface of the substrate.

7. The thin film transistor according to claim 6, wherein the oxide semiconductor layer contains In, Ga, Zn, and O.

8. The thin film transistor according to claim 6, wherein the source electrode, the drain electrode, and the gate electrode are formed by collective photolithography and collective wet etching.

9. A thin film transistor comprising:
a substrate;
a first oxide semiconductor layer formed on a first main surface of the substrate;
a second oxide semiconductor layer formed on a second main surface of the substrate;
a first transistor including
a first gate electrode formed on the first oxide semiconductor layer, and
a first source electrode and a first drain electrode formed on the second oxide semiconductor layer; and
a second transistor including
a second gate electrode formed on the second oxide semiconductor layer, and
a second source electrode and a second drain electrode formed on the first oxide semiconductor layer.

10. The thin film transistor according to claim 9, wherein the first source electrode or the first drain electrode and the second source electrode or the second drain electrode are arranged to overlap each other.

11. The thin film transistor according to claim 9, wherein a conductive type of the first oxide semiconductor layer and a conductive type of the second oxide semiconductor layer have opposite polarities, and the first transistor and the second transistor are structured in a complementary manner.

12. The thin film transistor according to claim 11, wherein the first drain electrode and the second drain electrode are arranged to overlap each other, a through hole is formed in the substrate in a region in which the first drain electrode and the second drain electrode overlap each other, and the first drain electrode and the second drain electrode are connected to each other via the through hole.

13. The thin film transistor according to claim 9, wherein the first oxide semiconductor layer or the second oxide semiconductor layer contains In, Ga, Zn, and O.

14. The thin film transistor according to claim 6, wherein the substrate is made of a high polymer film, and thickness of the substrate is 0.1 μm or more to 50 μm or less.

15. The thin film transistor according to claim 2, wherein the first oxide semiconductor layer or the second oxide semiconductor layer contains In, Ga, Zn, and O.

16. The thin film transistor according to claim 10, wherein a conductive type of the first oxide semiconductor layer and a conductive type of the second oxide semiconductor layer have opposite polarities, and the first transistor and the second transistor are structured in a complementary manner.

17. The thin film transistor according to claim 16, wherein the first drain electrode and the second drain electrode are arranged to overlap each other, a through hole is formed in the substrate in a region in which the first drain electrode and the second drain electrode overlap each other, and the first drain electrode and the second drain electrode are connected to each other via the through hole.

18. The thin film transistor according to claim 9, wherein the substrate is made of a high polymer film, and thickness of the substrate is 0.1 μm or more to 50 μm or less.
